(19) United States
(12) Patent Application Publication
(10) Pub. No.: US 2025/0285894 A1
(43) Pub. Date: Sep. 11, 2025

(54) SEMICONDUCTOR PROCESSING SYSTEM AND METHOD

(71) Applicant: NANYA TECHNOLOGY CORPORATION, New Taipei city (TW)

(72) Inventor: Jih-Cheng HUANG, New Taipei City (TW)

(21) Appl. No.: 18/598,742

(22) Filed: Mar. 7, 2024

(51) Int. Cl. H01L 21/67; H01L 21/66

(52) U.S. Cl. CPC H01L 21/67288; H01L 21/67132; H01L 22/12

(57) ABSTRACT

A semiconductor processing system includes an outer frame, a wafer processing equipment, an image capturing module, a tray, a driving mechanism and an inspection module. The wafer processing equipment is disposed within the outer frame. The image capturing module is disposed on one side of the wafer processing equipment, and having an image-capturing coverage. The tray loads a workpiece. The driving mechanism is movably disposed on the outer frame, fixedly connected to the tray for linearly moving the tray. The inspection module is electrically connected to the driving mechanism and the image capturing module. When the driving mechanism moves the tray loading the workpiece into the image-capturing coverage, the image capturing module captures an inspected image of the workpiece within the image-capturing coverage, and the inspection module performs a defect identification procedure for the workpiece shown in the inspected image.

### BACKGROUND

### Field of Disclosure

The present disclosure relates to a semiconductor processing system. More particularly, the present disclosure relates to a semiconductor processing system and method, which performs a defect identification procedure before a semiconductor process.

### Description of Related Art

Generally, the temporary bonding process is an essential process during a semiconductor through silicon via (TSV) process. In the temporary bonding process, adhesive is used to be respectively coated on contact surfaces of the finished wafer and the carrier board, and the finished wafer and the carrier board can be temporarily bonded together in the heat oven so as to perform the subsequent TSV manufacturing process.

However, if defects are occurred on the contact surfaces of the finished wafer and the carrier board or the adhesive coating layer on the contact surfaces thereof, or if no convenient or more effective inspection mechanism is provided in the temporary bonding process, flaws such as damage, dirt, or uneven color on a surface of the finished product may be formed after the process thereby hindering the subsequent TSV process.

Thus, the above-mentioned technology obviously still has inconveniences and defects, which are issues that the industry needs to solve urgently.

### SUMMARY

One aspect of the present disclosure is to provide a semiconductor processing system and method for solving the difficulties mentioned above in the prior art.

In one embodiment of the present disclosure, a semiconductor processing system is provided, and a semiconductor processing system includes an outer frame, a wafer processing equipment, at least one image capturing module, a tray, a driving mechanism and an inspection module. The wafer processing equipment is disposed within the outer frame, and provided with at least one feeding opening. The at least one image capturing module is disposed on one side of the wafer processing equipment, and provided with an image-capturing coverage. The tray is used to load a workpiece. The driving mechanism is movably disposed on the outer frame, fixedly connected to the tray, and used to linearly move the tray in a moving direction. The inspection module is electrically connected to the driving mechanism and the at least one image capturing module. When the driving mechanism moves the tray loading the workpiece thereon into the image-capturing coverage, the at least one image capturing module captures at least one inspected image of the workpiece within the image-capturing coverage, and the inspection module performs a defect identification procedure for the workpiece shown in the at least one inspected image.

In one embodiment of the present disclosure, a semiconductor processing system is provided, and the semiconductor processing system includes an outer frame, a wafer processing equipment, at least one image capturing module, a tray, a robot arm and an inspection module. The wafer processing equipment is disposed within the outer frame, and provided with at least one feeding opening. The tray loads a workpiece. The at least one image capturing module is disposed on one side of the wafer processing equipment for capturing at least one inspected image of the workpiece on the tray. The robot arm is located on the outer frame for moving the workpiece. The inspection module is electrically connected to the at least one image capturing module and the robot arm. When the inspection module determines that the workpiece is qualified through a defect identification procedure, the robot arm is triggered to deliver the workpiece from the tray into the wafer processing equipment through the at least one feeding opening.

In one embodiment of the present disclosure, a semiconductor processing method implemented by the aforementioned semiconductor processing system is provided, and the semiconductor processing method includes a number of steps described as follows. A first inspected image of a first workpiece is captured by the image capturing module. A determination is made as whether the first inspected image is defected by the inspection module. An adhesive is coated on the first workpiece by the wafer processing equipment when a determination is made that the first inspected image is not defected. A second inspected image of the first workpiece with the adhesive thereon is captured by the image capturing module. A determination is made as whether the second inspected image is defected by the inspection module. The first workpiece with the adhesive thereon is delivered into the wafer processing equipment by the robot arm when a determination is made that the second inspected image is not defected. A second workpiece is delivered into the wafer processing equipment by the robot arm. The first workpiece and the second workpiece are bonded together through the adhesive in the wafer processing equipment.

Thus, through the construction of the embodiments above, the semiconductor processing system and method of the disclosure can propose a convenient and effective inspection mechanism, which can effectively detect defects immediately and perform abnormal processing, instead of discovering defects only after the temporary bonding process.

The above description is merely used for illustrating the problems to be resolved, the technical methods for resolving the problems and their efficacies, etc. The specific details of the present disclosure will be explained in the embodiments below and related drawings.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain the principles of the present disclosure.

FIG. 1 is a schematic top view of a semiconductor processing system according to one embodiment of the present disclosure.

FIG. 2 is a schematic side view of the semiconductor processing system viewed in a direction D1 of FIG. 1.

FIG. 3 is a block diagram of the semiconductor processing system according to the embodiment of the present disclosure.

FIG. 4 is a schematic side view of the semiconductor processing system 10 viewed in a direction D2 of FIG. 1.

FIG. 5 is a flowchart of a semiconductor processing method implemented to the semiconductor processing system according to one embodiment of the present disclosure.

### DESCRIPTION OF THE EMBODIMENTS

Reference will now be made in detail to the present embodiments of the present disclosure, examples of which are illustrated in the accompanying drawings. Wherever possible, the same reference numbers are used in the drawings and the description to refer to the same or like parts. According to the embodiments, it will be apparent to those skilled in the art that various modifications and variations can be made to the structure of the present disclosure without departing from the scope or spirit of the present disclosure.

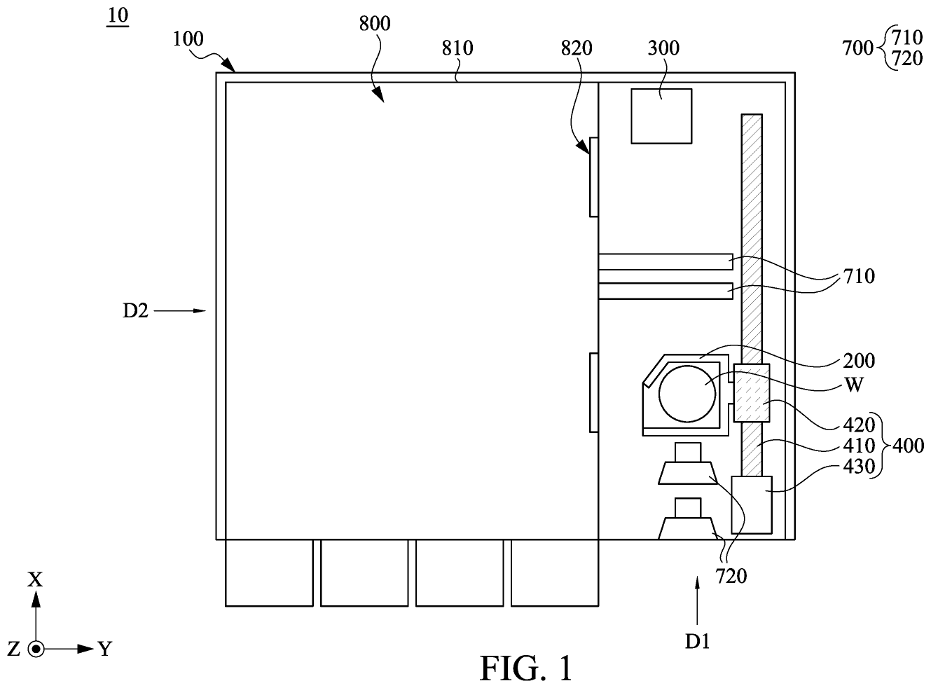

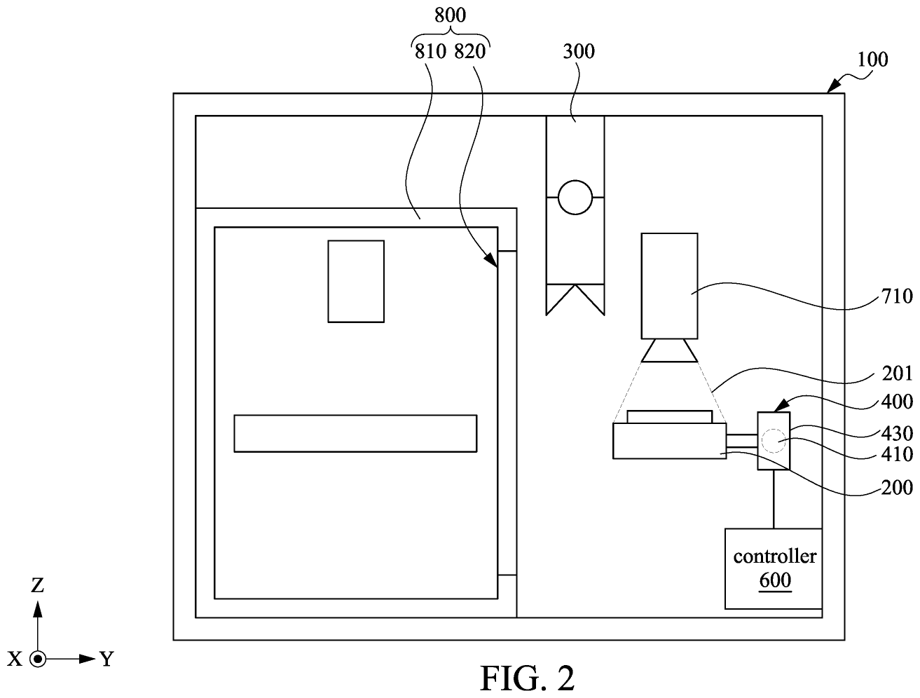

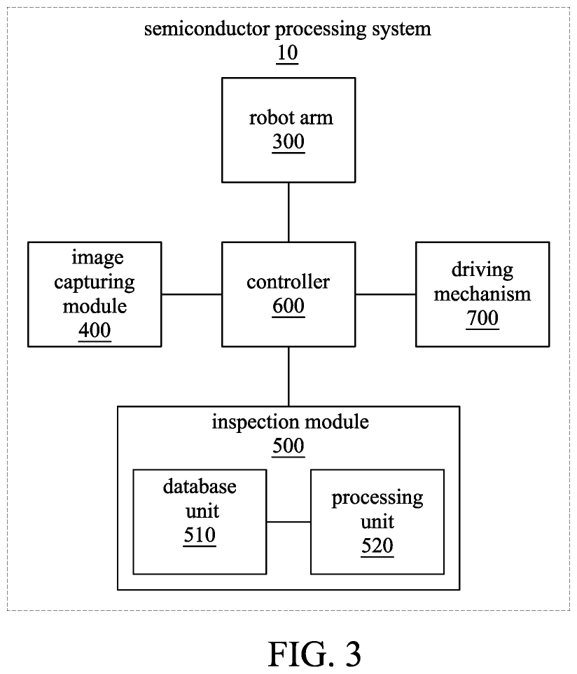

Reference is now made to FIG. 1 to FIG. 3, in which FIG. 1 is a schematic top view of a semiconductor processing system 10 according to one embodiment of the present disclosure, FIG. 2 is a schematic side view of the semiconductor processing system 10 viewed in a direction D1 (e.g., X axis) of FIG. 1, and FIG. 3 is a block diagram of the semiconductor processing system 10 according to the embodiment of the present disclosure. As shown in FIG. 1 to FIG. 3, in this embodiment, the semiconductor processing system 10 includes an outer frame 100, a tray 200, a robot arm 300, a driving mechanism 400, an inspection module 500, a controller 600, a plurality of image capturing modules 700 and a wafer processing equipment 800. The top surface 201 of the tray 200 can load a workpiece W thereon. In the embodiment, the tray 200 is located outside the wafer processing equipment 800, and the workpiece W, for example is, one of a carrier and a wafer, however, the disclosure is not limited thereto. The robot arm 300 is located on the outer frame 100 for delivering the workpiece W onto the tray 200 or away from the tray 200. The wafer processing equipment 800 is disposed within the outer frame 100, and used to process the workpiece W (e.g., carrier or wafer). The wafer processing equipment 800 is provided with plural (e.g., two) feeding openings 820 which are arranged separately on a chassis 810 of the wafer processing equipment 800. The feeding openings 820 are used as an inlet and an outlet for transferring the workpiece W by the robot arm 300, however, the disclosure is not limited to the number and the purpose of the feeding openings 820. For example, the wafer processing equipment 800 is temporary bonding equipment, however, the disclosure is not limited thereto, in another embodiment, the wafer processing equipment 800 may be debonding equipment.

The image capturing modules 700 are disposed on one side (right side or rear side) of the wafer processing equipment 800. Each of the image capturing modules 700 has an image-capturing coverage 701, in other words, each of the image capturing modules 700 grabs or captures at least one inspected image (e.g., video or photo) from the image-capturing coverage 701. In this embodiment, the image-capturing coverage 701 is in a line shape. In the embodiment, each of the image capturing modules 700 is fixedly connected to an inner side of the outer frame 100, however the disclosure is not limited thereto, in another embodiment, each of the image capturing modules 700 may be connected to an outer side of the outer frame 100.

The driving mechanism 400 is movably disposed on the outer frame 100, fixedly connected to the tray 200. The driving mechanism 400 is able to linearly move the tray 200 in a moving direction (e.g., X axis) to pass the workpiece W linearly through the image-capturing coverage 701 sequentially.

The inspection module 500 is electrically connected to the driving mechanism 400 and the image capturing module 700, and used to inspect any image to determine whether a defect is found in the image. The controller 600 is electrically connected to the driving mechanism 400, the inspection module 500, the image capturing modules 700, and the wafer processing equipment 800 for controlling them to work properly.

Therefore, when the driving mechanism 400 moves the tray 200 loading the workpiece W thereon into the image-capturing coverage 701 in the moving direction (e.g., X axis), one of the image capturing modules 700 captures an inspected image of the workpiece W within the image-capturing coverage 701, and the inspection module 500 performs the defect identification procedure for the workpiece W shown in the inspected image.

The defect identification procedure is performed for identifying the defect such as bump, depression, scratches, dust, uneven color, surface peeling, residual film pattern and water marks etc. In the defect identification procedure, a determination is made as whether the workpiece W shown in the inspected image is defected by the inspection module 500.

Specifically, as shown in FIG. 1 and FIG. 3, in the embodiment, each of the image capturing modules 700 includes a light source 710 and a line scan camera 720. The light source 710 can output sufficient lights to the workpiece W on the tray 200. The line scan camera 720 is electrically connected to the inspection module 500 and the light source 710, and able to linearly scan the workpiece W from one of opposite sides of the workpiece W to the other of the opposite sides thereof sequentially to correspondingly obtain line images. The inspection module 500 is able to sequentially combine the corresponding line images together to be the inspected image of the workpiece W. Since the line scan camera 720 is chosen in this embodiment, the inspected image combined by the line images can provide better definition for the workpiece W.

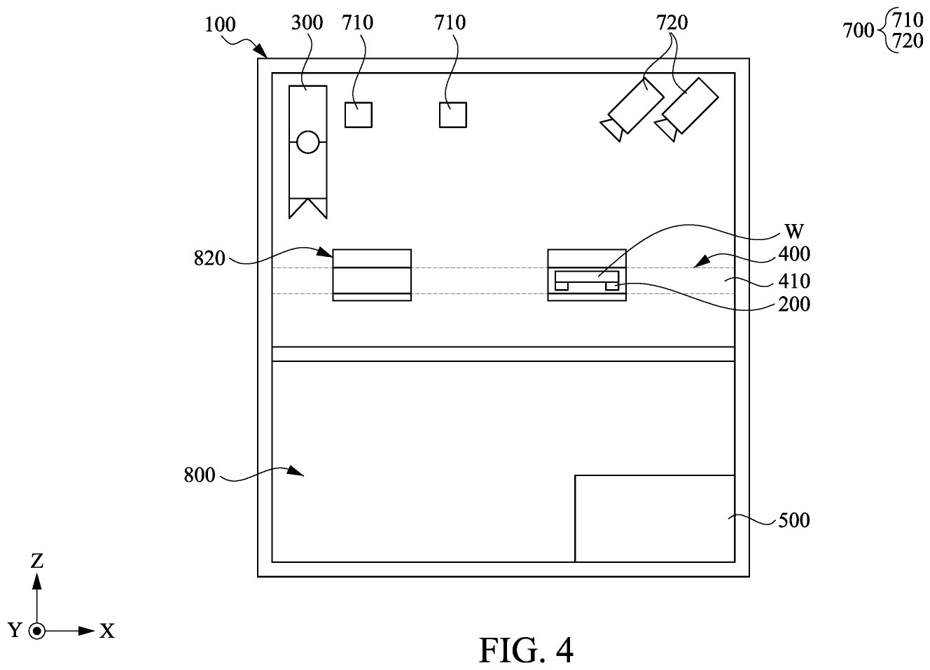

FIG. 4 is a schematic side view of the semiconductor processing system 10 viewed in a direction D2 (e.g., Y axis) of FIG. 1 through the wafer processing equipment 800. As shown in FIG. 4, in the embodiment, the image capturing modules 700 can be a bright field imaging module and a dark field imaging module which can effectively aim at various defects or color difference defects for obtaining appropriate images for defect identification. In the embodiment, the bright field imaging module can capture image with bright background for facilitating surface defect identification (e.g., dust, uneven color, residual film pattern and water marks), and the dark field imaging module can capture image with dark background for facilitating structural defect identification (e.g., depression, bump, surface peeling and scratch).

However, the disclosure is not limited thereto, in another embodiment, the image capturing module may have two light sources and single line scan camera for respectively providing bright field and dark field of image capturing.

In the embodiment, as shown in FIG. 1 and FIG. 3, the driving mechanism 400 includes a ball screw 410, a sleeve nut 420 and a screw-driving motor 430. A long axis direction (e.g., X axis) of the ball screw 410 is parallel to the moving direction (e.g., X axis) of the tray 200, orthogonal to a normal line (e.g., Z axis) of the top surface 201 of the tray 200, and also orthogonal to an opening direction (e.g., Y axis) of one of the feeding openings 820. The sleeve nut 420 is fixedly connected to the tray 200 and spirally engaged with the ball screw 410. The screw-driving motor 430 is electrically connected to the controller 600. Therefore, when the controller 600 instructs the screw-driving motor 430 to operate, the screw-driving motor 430 is coaxially connected to the ball screw for driving the ball screw 410 to rotate, thus, the sleeve nut 420 can be linearly moved in the long axis direction (e.g., X axis) of the ball screw 410 so as to move the tray 200 in a linear movement for passing the image-capturing coverage 701. In addition, the driving mechanism 400 may also move the tray 200 to one of the feeding openings 820 if necessary.

However, the disclosure is not limited thereto, in another embodiment, the driving mechanism 400 may be a stepper motor gradually moving the tray 200 in steps so that the workpiece W on the tray 200 linearly passes through the image-capturing coverage 701 sequentially.

The inspection module 500 includes a database unit 510 and a processing unit 520. The database unit 510 is stored with a variety of defect patterns. The processing unit 520 is electrically connected to the database unit 510 and the image capturing module 700 for comparing and determining whether at least one part of the inspected image of the workpiece W matches one of the defect patterns, and the inspection module 500 issues an alert and withdraws the workpiece W out of the outer frame 100 if any part of the inspected image of the workpiece W matches the aforementioned defect pattern. In the embodiment, the database unit 510 is, for example, a storage device such as non-volatile memory express (NVMe) storage devices, solid state drives (SSD) and hard disk drives (HDD); the processing unit 520 is, for example, a central processing unit (CPU), a microcontroller unit or a single-chip device having programs. However, the disclosure is not limited thereto.

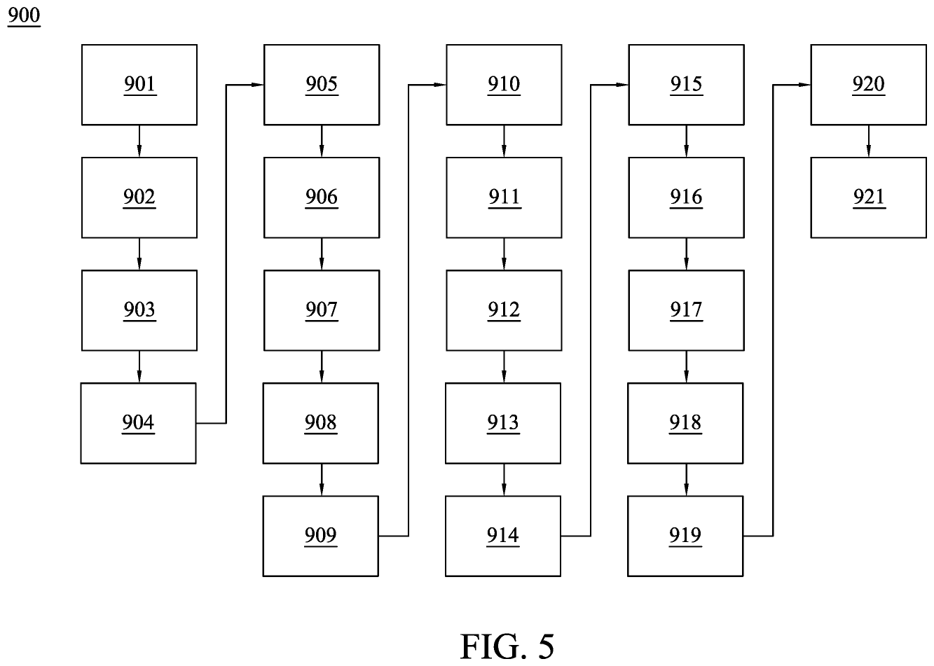

FIG. 5 is a flowchart of a semiconductor processing method implemented to the semiconductor processing system according to one embodiment of the present disclosure. As shown in FIG. 1 and FIG. 5, the semiconductor processing method includes step 901 to step 921. In step 901, a first workpiece (e.g., carrier) is delivered onto the tray 200 by the robot arm 300. In step 902, a first inspected image of the first workpiece loaded on the tray 200 is captured by the image capturing modules 700. In step 903, the defect identification procedure is performed by the inspection module 500 for the first workpiece shown in the first inspected image. In step 904, the first workpiece is delivered inside the wafer processing equipment (e.g., temporary bonding equipment) 800 via one of the feeding openings 820 when the first workpiece is qualified through the defect identification procedure, otherwise, the first workpiece is withdrawn out of the outer frame 100. In step 905, one surface of the first workpiece is coated with an adhesive layer (not shown in figures) thereon in the wafer processing equipment 800. In step 906, the first workpiece with the adhesive layer thereon is delivered onto the tray 200 through the other of the feeding openings 820 by the robot arm 300 after the tray 200 is moved to the other of the feeding openings 820. In step 907, a second inspected image of the first workpiece with the adhesive layer thereon is captured by the image capturing modules 700. In step 908, a defect identification procedure is performed by the inspection module 500 for the first workpiece shown in the second inspected image. In step 909, the first workpiece with the adhesive layer thereon is delivered into the wafer processing equipment 800 by the robot arm 300 when the first workpiece with the adhesive layer thereon is qualified through the defect identification procedure, otherwise, the first workpiece with the adhesive layer thereon is withdrawn out of the outer frame 100.

In step 910, a second workpiece (e.g., finished wafer) is delivered onto the tray 200 by the robot arm 300. In step 911, a third inspected image of the second workpiece loaded on the tray 200 is captured by the image capturing modules 700. In step 912, a defect identification procedure is performed by the inspection module 500 for the second workpiece shown in the third inspected image. In step 913, the second workpiece is delivered into the wafer processing equipment 800 via one of the feeding openings 820 when the second workpiece is qualified through the defect identification procedure otherwise, the second workpiece is withdrawn out of the outer frame 100. In step 914, the second workpiece is coated with an adhesive layer (not shown in figures) thereon in the wafer processing equipment 800. In step 915, the second workpiece with the adhesive layer thereon is delivered onto the tray 200 through the other of the feeding openings 820 by the robot arm 300 after the tray 200 is moved to the other of the feeding openings 820. In step 916, a fourth inspected image of the second workpiece with the adhesive layer thereon is captured by the image capturing modules 700. In step 917, a defect identification procedure is performed by the inspection module 500 for the second workpiece shown in the fourth inspected image. In step 918, the second workpiece with the adhesive layer thereon is delivered into the wafer processing equipment 800 when the second workpiece with the adhesive layer thereon is qualified through the defect identification procedure otherwise, the second workpiece with the adhesive layer thereon is withdrawn out of the outer frame 100. In step 919, the first workpiece and the second workpiece are bonded together as a stacked structure by their adhesive layers. In step 920, the stacked structure is heated to finish the temporary bonding. In step 921, the stacked structure is delivered back to the tray 200, and a defect identification procedure is performed by the inspection module 500 for the stacked structure shown in another inspected image captured by the image capturing modules 700 for inspecting the stacked structure.

It is noted, the defect identification procedure described above in the disclosure can be carried out in full inspection, sampling inspection or based on actual production needs. Also, in another embodiment, based on some requirement or restriction, the step 911 to step 918 or/and step 921 can be omitted in this disclosure.

In the embodiment, the inspection module 500 is one of an automated optical inspection (AOI) module and an artificial intelligence (AI) inspection module, however, the disclosure is not limited thereto. the controller 600 is, for example, a central processing unit (CPU), a microcontroller unit or a single-chip device having programs, however, the disclosure is not limited thereto.

In one embodiment of the present disclosure, a semiconductor processing system is provided, and a semiconductor processing system includes an outer frame, a wafer processing equipment, at least one image capturing module, a tray, a driving mechanism and an inspection module. The wafer processing equipment is disposed within the outer frame, and provided with at least one feeding opening. The at least one image capturing module is disposed on one side of the wafer processing equipment, and provided with an image-capturing coverage. The tray is used to load a workpiece. The driving mechanism is movably disposed on the outer frame, fixedly connected to the tray, and used to linearly move the tray in a moving direction. The inspection module is electrically connected to the driving mechanism and the at least one image capturing module. When the driving mechanism moves the tray loading the workpiece thereon into the image-capturing coverage, the at least one image capturing module captures at least one inspected image of the workpiece within the image-capturing coverage, and the inspection module performs a defect identification procedure for the workpiece shown in the at least one inspected image.

In one embodiment of the present disclosure, a semiconductor processing system is provided, and the semiconductor processing system includes an outer frame, a wafer processing equipment, at least one image capturing module, a tray, a robot arm and an inspection module. The wafer processing equipment is disposed within the outer frame, and provided with at least one feeding opening. The tray loads a workpiece. The at least one image capturing module is disposed on one side of the wafer processing equipment for capturing at least one inspected image of the workpiece on the tray. The robot arm is located on the outer frame for moving the workpiece. The inspection module is electrically connected to the at least one image capturing module and the robot arm. When the inspection module determines that the workpiece is qualified through a defect identification procedure, the robot arm is triggered to deliver the workpiece from the tray into the wafer processing equipment through the at least one feeding opening.

In one embodiment of the present disclosure, a semiconductor processing method implemented by the aforementioned semiconductor processing system is provided, and the semiconductor processing method includes a number of steps described as follows. A first inspected image of a first workpiece is captured by the image capturing module. A determination is made as whether the first inspected image is defected by the inspection module. An adhesive is coated on the first workpiece by the wafer processing equipment when a determination is made that the first inspected image is not defected. A second inspected image of the first workpiece with the adhesive thereon is captured by the image capturing module. A determination is made as whether the second inspected image is defected by the inspection module. The first workpiece with the adhesive thereon is delivered into the wafer processing equipment by the robot arm when a determination is made that the second inspected image is not defected. A second workpiece is delivered into the wafer processing equipment by the robot arm. The first workpiece and the second workpiece are bonded together through the adhesive in the wafer processing equipment.

Thus, through the construction of the embodiments above, the semiconductor processing system of the disclosure can propose a convenient and effective inspection mechanism, which can effectively detect defects immediately and perform abnormal processing, instead of discovering defects only after the temporary bonding process.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure covers modifications and variations of this disclosure provided they fall within the scope of the following claims and their equivalents.

What is claimed is:

1. A semiconductor processing system, comprising:
an outer frame;
a wafer processing equipment disposed within the outer frame, and provided with at least one feeding opening;
at least one image capturing module disposed on one side of the wafer processing equipment, and having an image-capturing coverage;
a tray used to load a workpiece;
a driving mechanism movably disposed on the outer frame, fixedly connected to the tray, for linearly moving the tray in a moving direction; and
an inspection module electrically connected to the at least one image capturing module,
wherein when the driving mechanism moves the tray loading the workpiece thereon into the image-capturing coverage, the at least one image capturing module captures at least one inspected image of the workpiece within the image-capturing coverage, and the inspection module performs a defect identification procedure for the workpiece shown in the at least one inspected image.

2. The semiconductor processing system of claim 1, wherein the at least one image capturing module comprises:
at least one light source configured to provide sufficient lights to the workpiece on the tray; and
a line scan camera electrically connected to the inspection module and the light source, and configured to linearly scan the workpiece from one of opposite sides of the workpiece to the other of the opposite sides thereof sequentially to correspondingly obtain line images as the image-capturing coverage is in a line shape,
wherein the line images are combined sequentially to be the at least one inspected image by the inspection module.

3. The semiconductor processing system of claim 1, wherein the at least one image capturing module is fixedly connected to one of an inner side and an outer side of the outer frame.

4. The semiconductor processing system of claim 1, wherein the at least one image capturing module comprises a bright field imaging module and a dark field imaging module.

5. The semiconductor processing system of claim 1, wherein the driving mechanism comprises:
a ball screw having a long axis direction that is parallel to the moving direction of the tray and orthogonal to an opening direction of the at least one feeding opening;
a sleeve nut fixedly connected to the tray and spirally engaged with the ball screw for linearly moving in the long axis direction of the ball screw; and
a screw-driving motor coaxially connected to the ball screw for driving the ball screw to rotate.

6. The semiconductor processing system of claim 1, wherein the inspection module comprises:
a database unit stored with a variety of defect patterns; and
a processing unit electrically connected to the database unit and the at least one image capturing module for comparing and determining whether at least one part of the at least one inspected image of the workpiece matches one of the defect patterns,
wherein when a determination is made that the at least one part of the at least one inspected image of the workpiece matches the one of the defect patterns, the inspection module issues an alert and withdraws the workpiece out of the outer frame.

7. The semiconductor processing system of claim 1, wherein the inspection module is an automated optical inspection (AOI) module or an artificial intelligence (AI) inspection module.

8. The semiconductor processing system of claim 1, wherein the wafer processing equipment is one of a temporary bonding equipment and a debonding equipment.

9. A semiconductor processing system, comprising:
an outer frame;
a wafer processing equipment disposed within the outer frame, and provided with at least one feeding opening;
a tray for loading a workpiece;
at least one image capturing module disposed on one side of the wafer processing equipment for capturing at least one inspected image of the workpiece loaded on the tray;
a robot arm located on the outer frame; and
an inspection module electrically connected to the at least one image capturing module,
wherein when the inspection module determines that the workpiece is qualified through a defect identification procedure, the robot arm is triggered to deliver the workpiece from the tray into the wafer processing equipment through the at least one feeding opening.

10. The semiconductor processing system of claim 9, wherein the at least one image capturing module is fixedly connected to one of an inner side and an outer side of the outer frame.

11. The semiconductor processing system of claim 9, wherein the at least one image capturing module comprises a bright field imaging module and a dark field imaging module.

12. The semiconductor processing system of claim 9, wherein the at least one image capturing module comprises:
at least one light source electrically configured to provide sufficient lights to the workpiece on the tray; and
a line scan camera electrically connected to the inspection module and the light source, and configured to linearly scan the workpiece from one of opposite sides of the workpiece to the other of the opposite sides thereof sequentially to correspondingly obtain line images,
wherein the line images are combined sequentially to be the at least one inspected image by the inspection module.

13. The semiconductor processing system of claim 12, further comprising:
a driving mechanism movably disposed on the outer frame, fixedly connected to the tray for linearly moving the tray in a moving direction to pass the workpiece through an image-capturing coverage of the at least one image capturing module.

14. The semiconductor processing system of claim 13, wherein the driving mechanism comprises:
a ball screw having a long axis direction being parallel to the moving direction of the tray, and orthogonal to an opening direction of the at least one feeding opening;
a sleeve nut fixedly connected to the tray and spirally engaged with the ball screw for linearly moving in the long axis direction of the ball screw; and
a screw-driving motor configured to drive the ball screw to rotate.

15. The semiconductor processing system of claim 9, wherein the inspection module comprises:
a database unit stored with a variety of defect patterns; and
a processing unit electrically connected to the database unit and the at least one image capturing module for comparing and determining whether at least one part of the at least one inspected image of the workpiece matches one of the defect patterns,
wherein when a determination is made that the at least one part of the at least one inspected image of the workpiece matches the one of the defect patterns, the inspection module issues an alert and withdraws the workpiece out of the outer frame.

16. The semiconductor processing system of claim 9, wherein the wafer processing equipment is one of a temporary bonding equipment and a debonding equipment.

17. The semiconductor processing system of claim 9, wherein the inspection module is an automated optical inspection (AOI) module or an artificial intelligence (AI) inspection module.

18. A semiconductor processing method implemented by the semiconductor processing system of claim 9, the semiconductor processing method comprising:
capturing a first inspected image of a first workpiece by the image capturing module;
determining whether the first inspected image is defected by the inspection module;
coating an adhesive on the first workpiece by the wafer processing equipment when a determination is made that the first inspected image is not defected;
capturing a second inspected image of the first workpiece with the adhesive thereon by the image capturing module;
determining whether the second inspected image is defected by the inspection module;
delivering the first workpiece with the adhesive thereon into the wafer processing equipment by the robot arm when a determination is made that the second inspected image is not defected;
delivering a second workpiece into the wafer processing equipment by the robot arm; and
bonding the first workpiece and the second workpiece together through the adhesive in the wafer processing equipment.

19. The semiconductor processing method of claim 18, wherein before the step of bonding the first workpiece and the second workpiece together, the semiconductor processing method further comprises:
capturing a third inspected image of the second workpiece by the image capturing module;
determining whether the third inspected image is defected by the inspection module;
coating an adhesive on the second workpiece by the wafer processing equipment when a determination is made that the third inspected image is not defected;
capturing a fourth inspected image of the second workpiece with the adhesive thereon by the image capturing module;
determining whether the fourth inspected image is defected by the inspection module; and
delivering the second workpiece with the adhesive thereon into the wafer processing equipment by the robot arm when a determination is made that the fourth inspected image is not defected.

20. The semiconductor processing method of claim 18, wherein the first workpiece is a carrier, the second workpiece is a wafer and the wafer processing equipment is a temporary bonding equipment.
